(19) United States
(12) Patent Application Publication
(10) Pub. No.: US 2011/0175183 A1
(43) Pub. Date: Jul. 21, 2011

(54) INTEGRATED PLASMONIC LENS PHOTODETECTOR

(75) Inventors: Bahram Nabet, Erdenheim, PA (US); James Anthony Shackleford, Philadelphia, PA (US); Richard R. Grote, Doylestown, PA (US); Jonathan E. Spanier, Bala Cynwyd, PA (US)

(73) Assignee: DREXEL UNIVERSITY, Philadelphia, PA (US)

(21) Appl. No.: 12/856,506

(22) Filed: Aug. 13, 2010

Related U.S. Application Data
(60) Provisional application No. 61/234,193, filed on Aug. 14, 2009.

(51) Int. Cl. H01L 31/108; H01L 31/18

(52) U.S. Cl. 257/432; 438/71; 257/E31.128; 257/E31.066

(57) ABSTRACT

Metal-semiconductor-metal (MSM) photodetectors may see increased responsivity when a plasmonic lens is integrated with the photodetector. The increased responsivity of the photodetector may be a result of effectively ‘guiding’ photons into the active area of the device in the form of a surface plasmon polariton. In one embodiment, the plasmonic lens may not substantially decrease the speed of the MSM photodetector. In another embodiment, the Shottkey contacts of the MSM photodetector may be corrugated to provide integrated plasmonic lens. For example, one or more of the cathodes and anodes can be modified to create a plurality of corrugations. These corrugations may be configured as a plasmonic lens on the surface of a photodetector. The corrugations may be configured as parallel linear corrugations, equally spaced curved corrugations, curved parallel corrugations, approximately equally spaced concentric circular corrugations, chirped corrugations or the like.

### CROSS REFERENCE TO RELATED CASES

This application claims the benefit of priority from U.S. provisional application No. 61/234,193 filed Aug. 14, 2009, the entirety of which is herein incorporated by reference.

### GOVERNMENT RIGHTS

The invention disclosed herein was funded at least in part by the National Science Foundation (NSF) Grant No. ECCS 0702716 and Army Research Office (ARO) Grant No. W911NF-08-1-0067. Accordingly, the government may have some rights to the disclosed invention.

### BACKGROUND

Metal-semiconductor-metal (MSM) photodetectors may contain two Schottky contacts, i.e., two conductive electrodes on a semiconductor material. During operation, some electric voltage is applied to the anode and cathode. Incident light on the semiconductor between the anode and cathode generates electric carriers (electrons and holes), which are transported by the electric field and collected at the contacts thus forming a photocurrent.

MSM detectors can operate as fast and often faster than PN junction, PIN, and avalanche photodiodes. MSM detection bandwidths can reach hundreds of gigahertz, which may make them useful in high-speed applications such as optical fiber communications.

The responsivity of a photodetector is a measure of the electrical output for each unit of optical input to the photodetector. It may be desirable to increase the responsivity of a photodetector, particularly if such an increase may be gained without a loss in the speed of the detector.

### SUMMARY

Disclosed herein are metal-semiconductor metal (MSM) photodetectors wherein a plasmonic lens is integrated on the surface of the photodetector. Placing a plasmonic lens on the surface of a photodetector may, among other things, increase the responsivity of the photodetector by effectively guiding photons that would normally be reflected off of the surface of the MSM photodetector into the active area of the device in the form of a surface plasmon polariton. In one embodiment, the plasmonic lens may not substantially decrease the speed of the MSM photodetector.

In one embodiment, the Schottky contacts of the MSM photodetector may be corrugated to provide integrated plasmonic lens. For example, one or more of the cathodes and anodes can be modified to create a plurality of corrugations. These corrugations may be configured as a plasmonic lens on the surface of a photodetector. The corrugations may be configured as parallel linear corrugations, equally spaced curved corrugations, curved parallel corrugations, approximately equally spaced concentric circular corrugations, as chirped gratings or the like.

In an embodiment, the corrugations may be designed to selectively couple light of a particular wavelength with the photodetector. For example, the corrugations may have a periodic spacing based on a particular wavelength. In an embodiment, the corrugations may be spaced based on one or more of the wavelength of interest, the type of material being corrugated, the and/or the angle of incidence of the incoming light impinging on the corrugations.

In one embodiment, the corrugations may be designed to couple light having a wavelength of about 830 nm. When the metal selected for the corrugations is gold, the period of the corrugations is about 814 nm. Further the groove to pitch ratio of the corrugations may be about one half, and the height of the corrugations in the range of about 20 nm-30 nm with a full height of the electrical contacts of about 100 nm.

### BRIEF DESCRIPTION OF THE DRAWINGS

FIG. 1 depicts a scanning electron microscope micrograph of a metal semiconductor metal photodetector with a plasmonic lens.

FIG. 2 depicts a view of a sample plasmonic lens integrated in a metal semiconductor metal (MSM) photodetector.

FIG. 3 depicts steps in a sample fabrication method for an integrated plasmonic lens photodetector.

FIG. 4 depicts steps in a sample fabrication method for an integrated plasmonic lens photodetector.

FIG. 5 shows the final result with the two contact pad, the electrical contacts with the grating, the active area and the plasmonic lens.

FIGS. 6(a)-(d) are scanning electron microscope images at different magnifications of an MSM photodetector with an integrated plasmonic lens.

FIGS. 7(a)-(d) are scanning electron microscope images at different magnifications of an MSM photodetector with a circular integrated plasmonic lens.

FIG. 8 depicts a graph of the photocurrent time response of an MSM photodetector both with and without a plasmonic lens.

FIG. 9 depicts an example graph for the photocurrent obtained with and without a plasmonic lens integrated with an MSM photodetector.

### DETAILED DESCRIPTION OF ILLUSTRATIVE EMBODIMENTS

A plasmonic lens may rely on the effects of plasmonics. A plasmon is a quantum of plasma oscillation. More specifically, plasmons are oscillations of the free electron gas densities, which may be at optical frequencies. Plasmons may couple with photons to create plasmon-polaritons (PP). Surface plasmons are confined to surfaces of materials the free electrons on the surface of a metal. As described herein, conductive corrugations may take advantage of surface plasmon polaritons when they interacts with a photon to guide, redirect and otherwise focus the photons to an area where they can be absorbed thus creating electron hole pairs in the active area of a MSM photodetector to increase the responsivity of the photodetector to the photon.

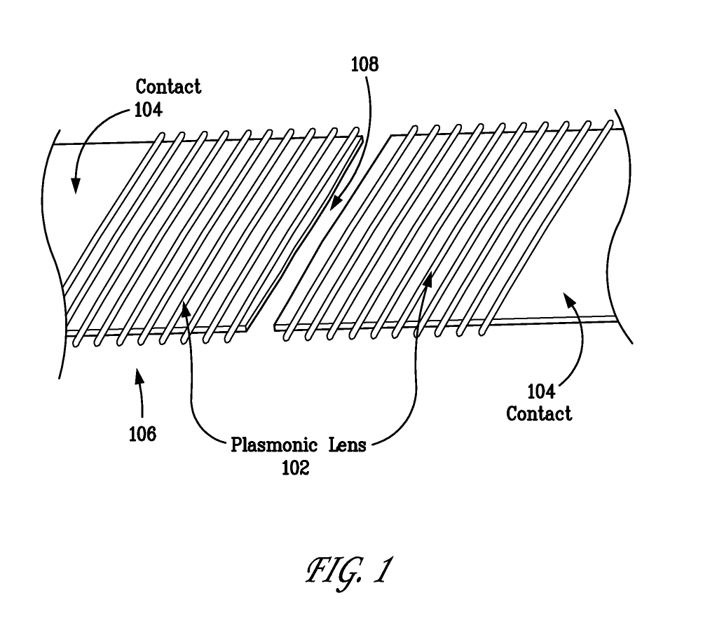

FIG. 1 depicts an embodiment of a MSM photodetector integrated with a plasmonic lens. In FIG. 1, a semiconducting substrate 106 is provided, wherein the substrate 106 is the semiconducting portion of the MSM photodetector. The substrate of the MSM photodetector can be any semiconductor known in the art that can be comprised as the base substrate for a MSM photodetector. In one embodiment the MSM substrate is comprised of a Group IV, Group III-IV, Group II-VI, Group I-VII, Group IV-VI, Group V-VI, Group II-V, organic, or magnetic semiconducting material.

The substrate 106 may be of any shape and size suitable for use as the substrate in a MSM photodetector. For example, the substrate 106 may be square, rectangular, spherical, cylindrical, triangular, circular, elliptical, amorphous, any type of polygon or ellipsoid. The substrate 106 can have a surface for integration of an anode and a cathode and can have a surface for integration of a plasmonic lens 102. In one embodiment, the surface comprising the integration of the cathode and anode is the same surface that integrated the plasmonic lens.

In one embodiment the substrate 106 of the MSM photodetector may comprise an undoped GaAs substrate. In another embodiment, the substrate 106 of the MSM photodetector may comprise a doped GaAs substrate.

The MSM photodetector integrated with a plasmonic lens may comprise electrical contacts 104 on the same surface of the substrate wherein a first contact is an anode and a second contact is a cathode. The electrical contacts 104 may be made of any conductive material suitable for use as an electrical contact in a MSM photodetector. In one embodiment, the conductive material may be a metallic material. The electrical contacts 104 may be of any shape, including but not limited to square, rectangular, cylindrical, circular, elliptical or ellipsoidal, polygonal or amorphous. The thickness of the electrical contacts 104 may vary depending on if it is in a peak or a valley of the grating.

The MSM photodetector integrated with a plasmonic lens may comprise a plasmonic lens 102. In one embodiment, the plasmonic lens may be integrated directly on the substrate 104. In another embodiment, one or more layers of any material, including the cathode and anode may be positioned in between the plasmonic lens 102 and the substrate 104.

The plasmonic lens 102 may comprise one or more sets of corrugations, where corrugations are regularly spaced ridges of material. The corrugations may be linear parallel corrugations, curved parallel corrugations, concentric circle corrugations, or the like. The corrugation ridges may have peaks which may be regularly spaced and they may have valleys which may also be regularly spaced. Peaks and valleys are discussed in greater detail below.

The corrugations may cover any area of the cathode, anode or other surface. In one embodiment, a set of corrugations may cover an entire surface area of a cathode, anode or other surface, while in another embodiment, the corrugations may cover only a small portion of the cathode, anode, or other surface, or any portion in between. The corrugations may be situated next to or near an absorption area.

In one embodiment, the plasmonic lens 102 comprises corrugations of the electrical contacts 104. In such an embodiment the corrugations may be spaced at regular intervals on the anode and cathode, and the anode and cathode may have corrugations spaced at the same intervals.

In one embodiment, the spacing of the corrugations in a plasmonic lens may be selected based on one or more of the wavelength of interest, the substrate material, the conductive material comprising the corrugations or the angle of incidence of the incoming light. In one embodiment, the spacing of the corrugations is selected based on the formula:

$${k}_{\vert \vert} = \frac{ω}{c} sin θ \pm Δ k = \frac{ω}{c} \sqrt{\frac{{ε}_{d} {ε}_{m}}{{ε}_{d} + {ε}_{m}}} = {k}_{sp} , \\ where$$

$$Δ k = \frac{2 π l}{a} , l = 1 , 2 , 3 , … .$$

Here Δk is the momentum required to satisfy the dispersion relation in such a way to allow for resonant coupling between incident photons and electrons in the MSM photodetector coupled to a plasmonic lens. Here k₁₁ is the component of the incident light wave vector parallel to the device surface, c is the speed of light and the lights angle of incidence is θ with respect to the device normal. Kₛₚs the surface plasmon wave vector, α is the grating period, w is the frequency of the light, and ε_{d} and εₘ are, respectively dielectric functions of air and metal.

The absorption area 108 of the substrate 106 may define the aperture of the plasmonic lens. In one embodiment, a slit between the anode and cathode may be the absorption area 108 of the MSM photodetector. The absorption area 108 may be of any size suitable for absorbing radiation from photons or plasmon polaritons. The absorption area 108 may be of any shape as well, including but not limited to polygonal, rectangular, a slit, circular, elliptical, amorphous and the like.

In one embodiment, the size of the absorption area 108 may be selected based on the wavelength of interest. In another embodiment, the width of the absorption area 108 may be about 1 um and the length of the absorption area may be equal to the length of the electrical contacts 104 or the plasmonic lens 102 as depicted in FIG. 1.

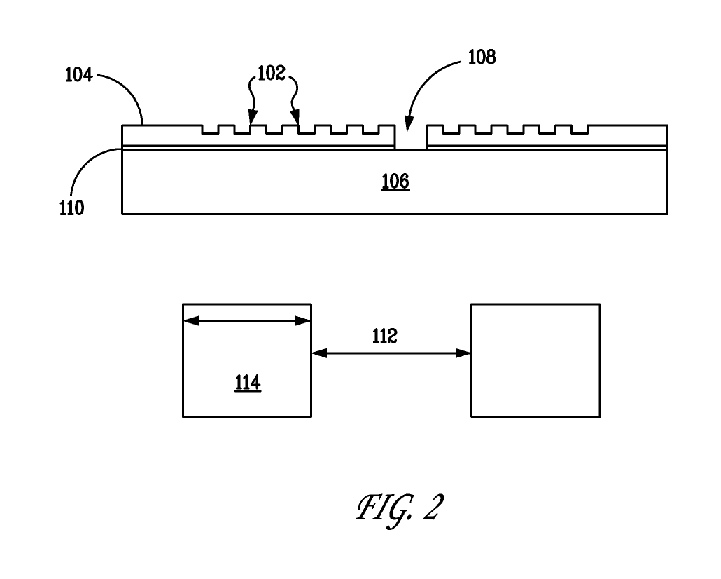

FIG. 2 depicts a cross section of an example MSM photodetector with an integrated plasmonic lens. As discussed above with respect to FIG. 1, the MSM photodetector may have a plasmonic lens 102, electrical contacts 104, a semiconducting substrate 106 and an absorption area 108.

FIG. 2 also depicts layer deposited between the electrical contacts and plasmonic lens and the substrate. In one embodiment, this may be an adhesive layer. According to one embodiment, any material that may be adhesive between a semiconducting material and a metal may comprise layer 110. In another embodiment, layer 110 may be a layer of Cr may be deposited on the substrate 106. On top of this Cr substrate may be added a conductive deposition 104 and 102 which may form a cathode, an anode, the plasmonic lens, or any combination thereof. After the deposition of these layers, the layers may be etched in order to create the corrugations on the surface of the photodetector.

FIG. 2(b) depicts a close up of two corrugations. As shown in FIG. 2(b), the corrugations may have a width 114 and a space between them 112. This spacing may be at regular intervals and may depend on the conductive substance, the wavelength of interest, the incident angle of light on the corrugated surface, or the like. The corrugations may be of any shape sufficient to create a plasmonic lens. In one embodiment, the corrugations are rectangular. In other embodiments, the corrugatins may be square, domed, triangular, amorphous, diamond shapded, cylindrical, spherical or the like.

In one embodiment, aspects of the plasmonic lens, such as, for example efficiency and the like may be related to the aspects of the corrugations and the electrical contacts. For example, modeling and simulations can be run for corrugations having different heights, for corrugation peaks 114 having different widths and for corrugations having different valley widths 112. Further, the thickness of the electrical contact from the base to the peak height may also be related to aspects of the plasmonic lens.

An embodiment has the peak width 114 and the valley width 112 equal to each other. Another embodiment involves a peak width 114 and a valley width 112 where the two widths are not equal to each other.

In an embodiment, the corrugations have a period of about 814 nm, a depth of about 20 nm to about 30 nm, and a thickness from peak to the adhesive layer of about 100 nm. This embodiment is merely an example of potential dimensions for a corrugated surface of a plasmonic lens. In other embodiments, the period may be in the range of from about 400 nm-1700 nm, the depth of the corrugations may be in the range of from about 1 nm to about 100 nm, with a thickness from the peak to the adhesive layer of from about 10 nm to about 1500 nm.

The layers of substrate, adhesive, electrical contacts, plasmonic lenses and any other layers may be deposited or grown by any method known in the art. In one embodiment, a substrate is created and various layers may be deposited via spin deposition, vacuum deposition, wet chemistry and the like on the substrate. After deposition, etching, wet chemistry and the like may take place. The process of deposition, etching, removing layers and the like may take place any number of time and in any order to provide a MSM photodetector with an integrated plasmonic lens. These processes are only examples of processes by which the device may be fabricated, and those mentioned is in no way limiting on the methods of fabrication that may be known to those skilled in the art and used in making a MSM photodetector with an integrated plasmonic lens.

In one embodiment, one or more integrated plasmonic lens MSM photodetectors may be used as a photodetector in fiber optics communications. The plasmonic lenses and photodetectors may be configurable to detect one or wavelengths of light for use in fiber optics.

In another embodiment, one or more integrated plasmonic lens photodetectors may also be used in solar panels and the like.

### Experimental Setup:

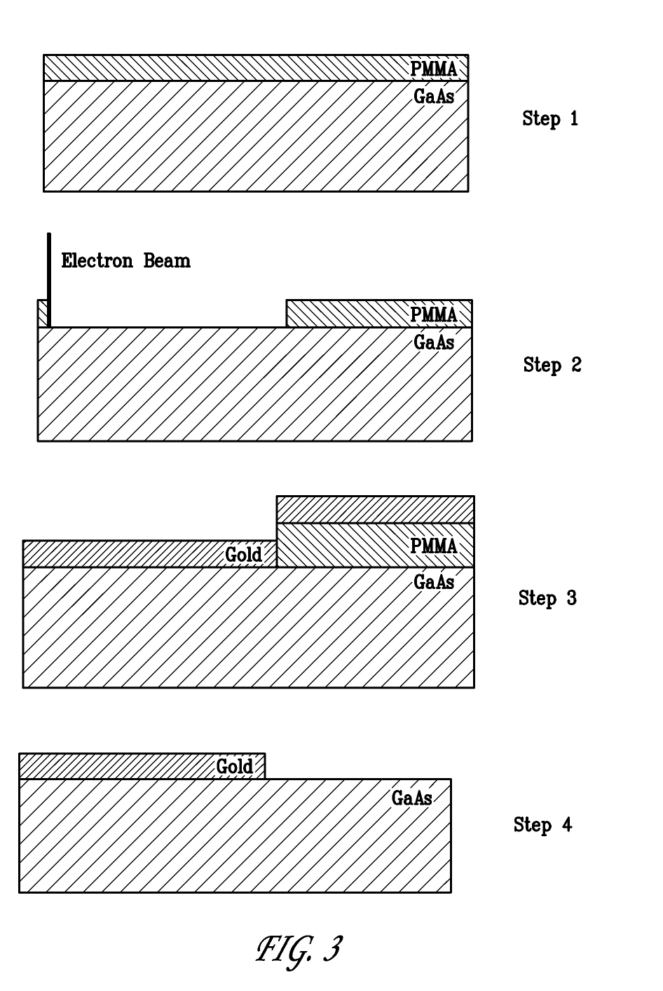

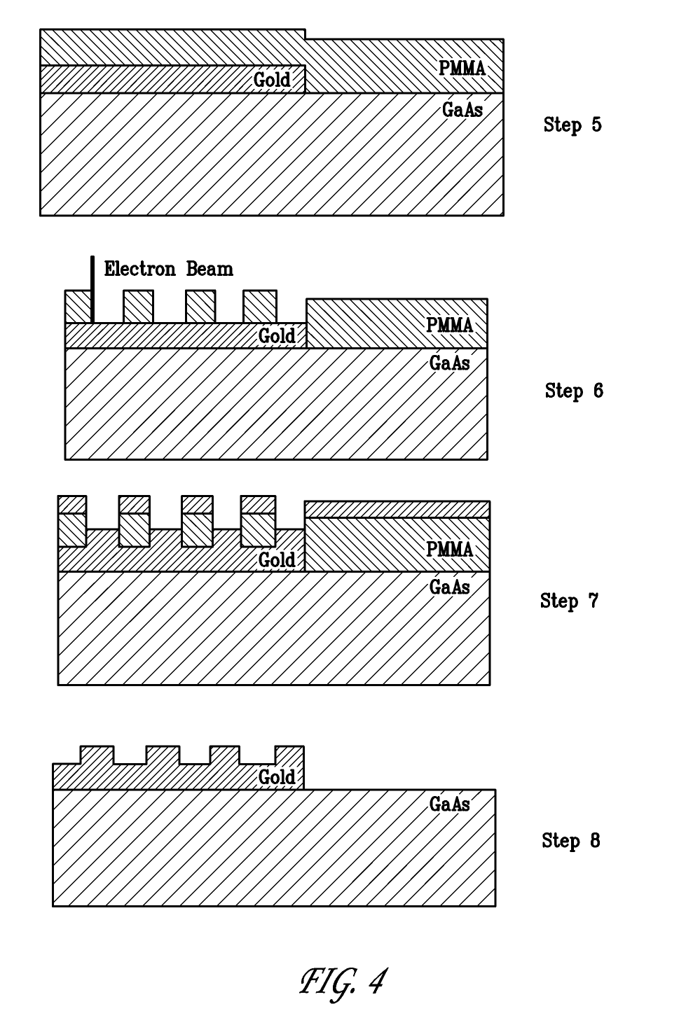

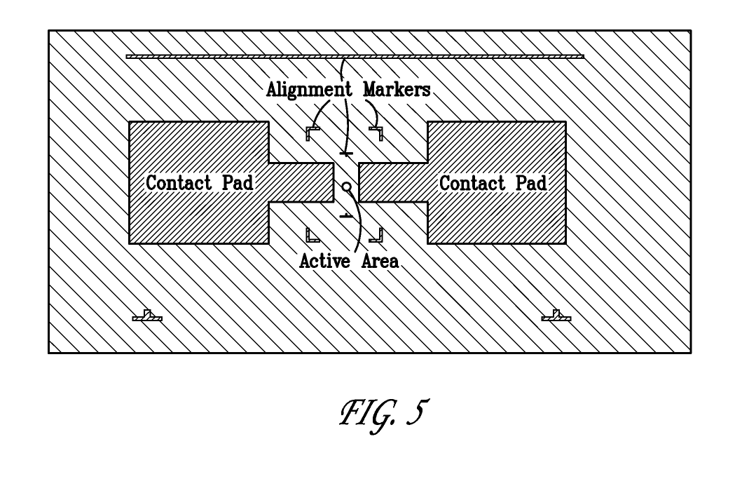

Several of the devices described herein were constructed and experiments were performed on them. The fabrication of the experimental devices started with a piece of intrinsic GaAs wafer and spin coating it with 950K PMMA as shown in step 1 of FIG. 3, which was then baked into the substrate. Next, the MSM device was written into using a focused electron beam of a scanning electron microscope as shown in Step 2 of FIG. 3. During this phase, only the MSM structures are being written, the corrugated structure of the plasmonic lens was not written during this phase. Metal deposition takes place after the scanning electron microscope marking, here a thin layer of chromium (not shown) for adhesion and gold on top as shown in Step 3 of FIG. 3. Acetone is then used to dissolve the PMMA as shown in Step 4 of FIG. 3. A second spin coat of 950 PMMA is added as Step 5 in FIG. 4. Grating lithography then writes gratings, in this instance, at 814 nm periodicity at Step 6 of FIG. 4. Next, a second layer of gold is deposited to increase the thickness of the gold layer and form the grating at step 7 of FIG. 4. The PMMA and excess gold are then removed with acetone, leaving a grating as shown in Step 8 of FIG. 5.

FIG. 5 shows the final result with the two contact pad, the electrical contacts with the grating, the active area and the plasmonic lens.

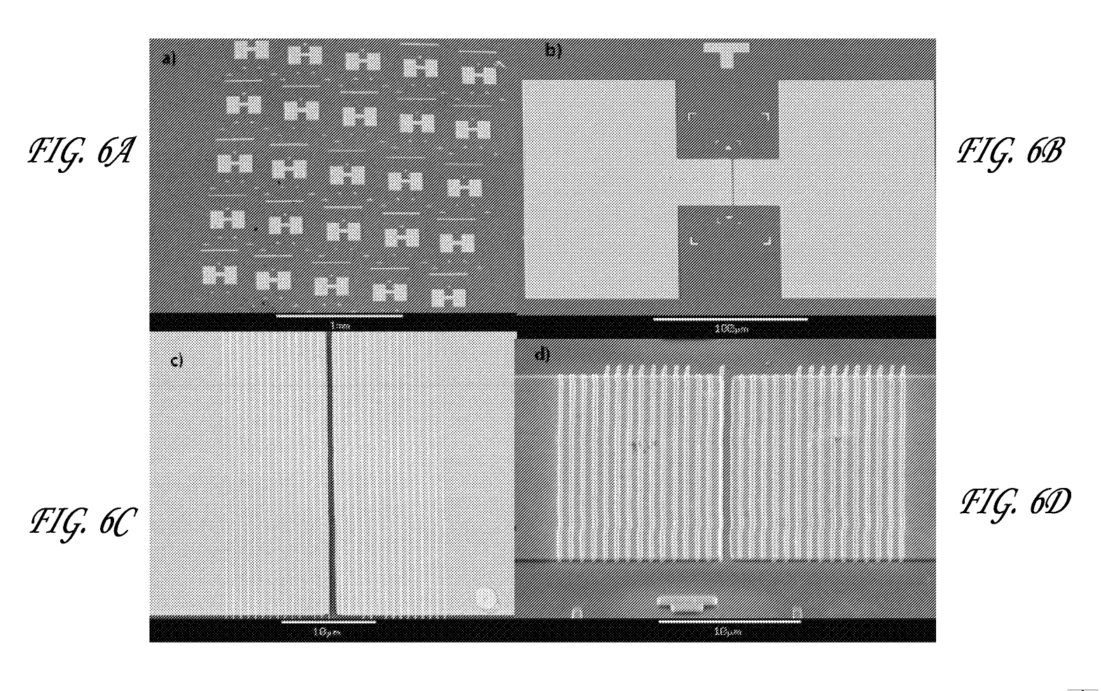

FIG. 6(a)-(d) depicts scanning electron microscope images at different magnifications of an MSM photodetector with an integrated parallel linear plasmonic lens. FIG. 6(a) has the lowest magnification and depicts and array of MSM photodetectors with parallel linear plasmonic lenses. FIG. 6(b) depicts a single MSM photodetector with parallel linear plasmonic lenses. The larger block can be electrical contacts and the like. The extensions towards the center may be the electrical contacts and/or the plasmonic lens. FIG. 6(c)-(d) depict close ups of the parallel linear plasmonic lens and absorption areas of a MSM photodetector with a parallel linear plasmonic lens.

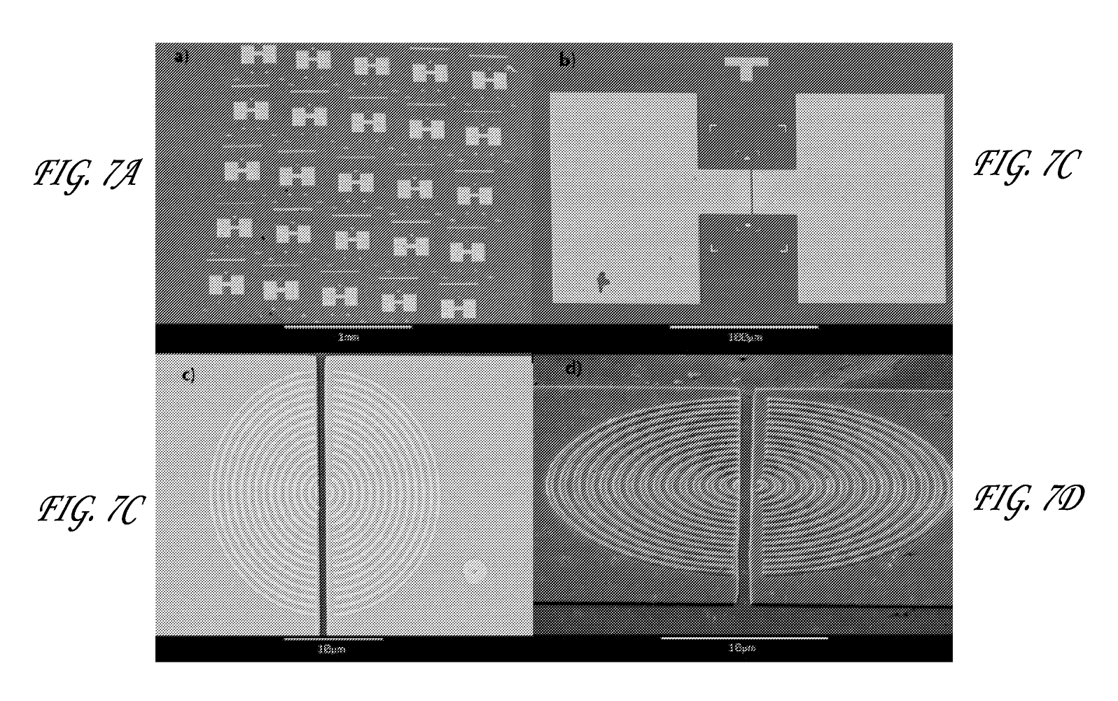

FIG. 7 (a)-(d) depicts scanning electron microscope images at different magnifications of an MSM photodetector with an integrated circular plasmonic lens. FIG. 7(a) has the lowest magnification and depicts and array of MSM photodetectors with circular plasmonic lenses. FIG. 7(b) depicts a single MSM photodetector with circular plasmonic lenses. The larger block can be electrical contacts and the like. The extensions towards the center may be the electrical contacts and/or the plasmonic lens. FIG. 6(c)-(d) depict close ups of the circular plasmonic lens and absorption areas of a MSM photodetector with a circular plasmonic lens.

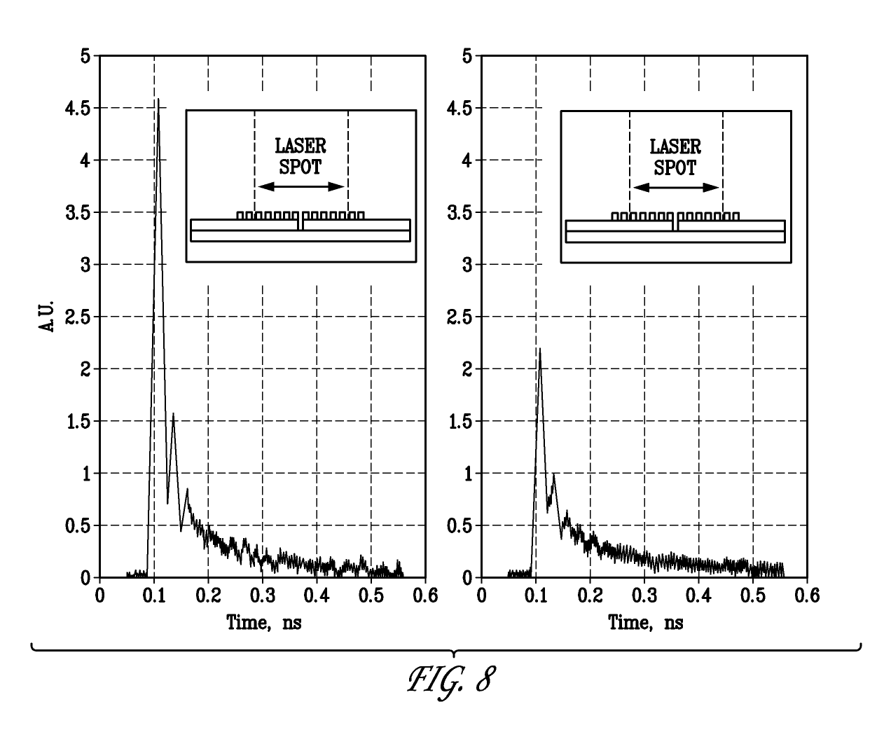

FIG. 8 depicts experimentally produced graphs comparing the time response for both a plasmonically enhanced MSM photodetector and an MSM photodetector without an integrated plasmonic lens. Both devices used in the experiment were fabricated on the same sample/substrate are are otherwise identical. The y-axis of the graph is in arbitrary units proportional to photocurrent and is identical for both graphs. Results show approximately a factor of two increase in peak response with the addition of the plasmonic lens. The full width half maximum (FWHM) of the transient response for both devices is measured to be around 15 ps. The fall time for both devices is also approximately equal, which indicates that the integration of the plasmonic lens may provide an increased responsivity without negatively affecting device speed.

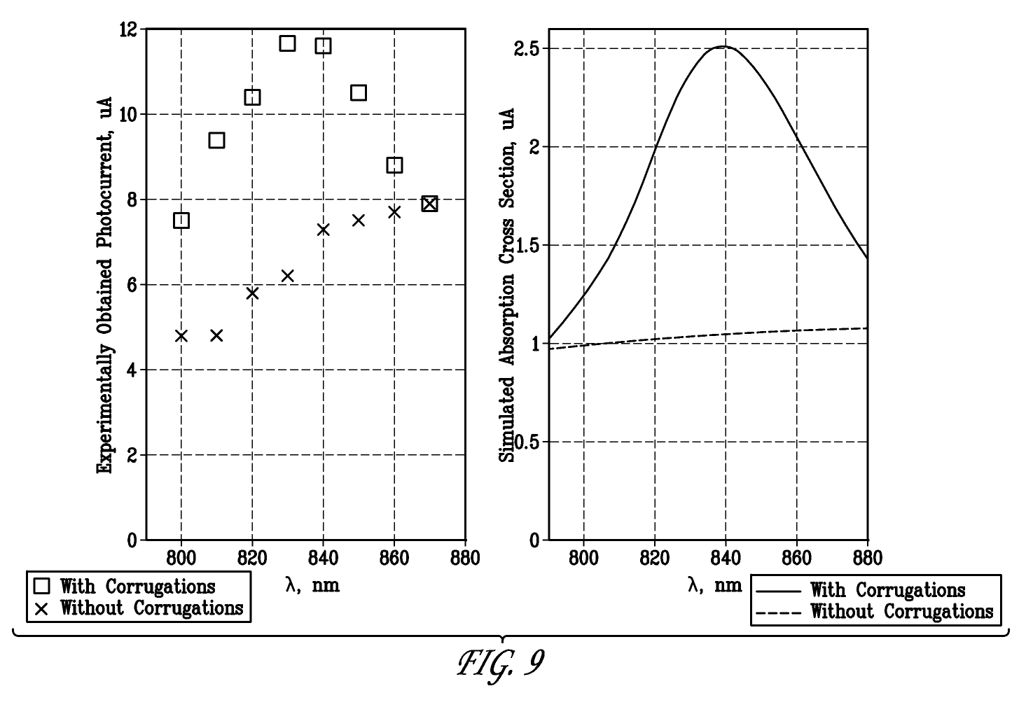

FIG. 9 depicts an experimentally produced graph for the photocurrent obtained using devices both with and without a plasmonic lens integrated with an MSM photodetector. In the experiment, to obtain the dependence of the photocurrent on wavelength, the same 10 um laser spot was placed at the center of the active area of the plasmonic device and the time averaged photocurrent was measured for a wavelength of 800 nm through 870 nm in 10 nm steps. Biasing voltage of 5 V dc was placed across the device an the experiment was repeated for the MSM photodetector with and without corrugations. The left panel of FIG. 9 compares the experimentally obtained response of the device with the plasmonic lens and the device without the plasmonic lens. The plasmonically enhanced photodetector displays wavelength selectivity, which manifests as a peak in photocurrent of about 6.1 uA for a wavelength of 830 nm. Normalizing to the incident power, this results in device responsivities of 0.14 and 0.075 A/W respectively. Overall, this indicates almost a factor of two increasing responsivity with the addition of the plasmonic lens.

The right panel of FIG. 9 shows the simulated flux density that is guided through the aperture of lensed and regular devices using the MIT electromagnetic equation propagation simulator. This is preformed by solving Maxwell's equations in two dimensions and exploiting device symmetry. Electron behavior within the metal may be implemented utilizing the Drude-Lorentz model thus forming a physically accurate description of the dielectric function for gold. Simulation results closely mirror experimental data.

Additionally, the subject matter of the present disclosure includes combinations and subcombinations of the various processes, systems and configurations, and other features, functions, acts, and/or properties disclosed herein, as well as equivalents thereof.

What is claimed:

1. A method for increasing the responsivity of a metal semiconductor metal photodetector, the method comprising:
integrating a conductive anode on a semiconductor;
integrating a conductive cathode on the semiconducting material; and
integrating at least one set of corrugations with the semiconducting material.

2. The method of claim 1 wherein the corrugations are approximately evenly spaced.

3. The method of claim 1 further comprising integrating the at least one set of corrugations in the conductive anode.

4. The method of claim 1 further comprising integration the at least one set of corrugations in the conductive cathode.

5. The method of claim 1 further comprising spacing the at least one set of corrugations based on a wavelength.

6. The method of claim 1 further comprising spacing the at least one set of corrugations based on a material used as the conductive anode.

7. The method of claim 1 further comprising spacing the at least one set of corrugations based on an incident angle of incoming light impinging on the set of corrugations.

8. The method of claim 1 wherein the conductive anode and the conductive cathode comprise gold.

9. The method of claim 3 wherein the wavelength is about 830 nm.

10. The method of claim 9 wherein the corrugation spacing is about 814 nm.

11. The method of claim 1 wherein the semiconducting material is GaAs.

12. The method of claim 1 wherein the corrugations are linear.

13. The method of claim 1 wherein the corrugations are curved.

14. An integrated plasmonic lens photodetector comprising:
a semiconducting material;
a conductive anode integrated on a surface of the semiconducting material;
a conductive cathode integrated on the surface of the semiconducting material; and
a plasmonic lens,
wherein the plasmonic lens is integrated with the semiconducting material.

15. The integrated plasmonic lens photodetector of claim 14 wherein the conductive anode comprises the plasmonic lens.

16. The integrated plasmonic lens photodetector of claim 14 wherein the conductive cathode comprises the plasmonic lens.

17. The integrated plasmonic lens photodetector of claim 14 wherein the plasmonic lens comprises at least one corrugated surface wherein each corrugated surface comprising a set of corrugations.

18. The integrated plasmonic lens photodetector of claim 17 wherein the corrugations in the set of corrugations are spaced at approximately regular intervals.

19. The integrated plasmonic lens photodetector of claim 18 further comprising spacing the set of corrugations based on one or more properties of the conductive anode.

20. The integrated plasmonic lens photodetector of claim 18 further comprising spacing the set of corrugations based on one or more properties of the conductive cathode.

21. The integrated plasmonic lens photodetector of claim 18 further comprising spacing the set of corrugations based on a wavelength.

22. The integrated plasmonic lens photodetector of claim 18 further comprising spacing the set of corrugations based on the angle of incidence of light impinging on the set of corrugations.

23. The integrated plasmonic lens photodetector of claim 18 wherein the corrugations are configured linearly.

24. The integrated plasmonic lens photodetector of claim 18 wherein the corrugations are curved.

25. The integrated plasmonic lens photodetector integrated plasmonic lens photodetector of claim 14 wherein the conductive anode and conductive cathode comprise gold.

26. The integrated plasmonic lens photodetector of claim 21 wherein the wavelength is about 830 nm.

27. The integrated plasmonic lens photodetector of claim 26 wherein the corrugation spacing is about 814 nm.

28. The integrated plasmonic lens photodetector of claim 14 wherein the semiconductor comprises GaAs.
